(19) United States
(12) Patent Application Publication
(10) Pub. No.: US 2025/0241106 A1
(43) Pub. Date: Jul. 24, 2025

(54) MICRO LED DISPLAY PANEL

(71) Applicant: JADE BIRD DISPLAY (SHANGHAI) LIMITED, SHANGHAI (CN)

(72) Inventors: Qunchao XU, Shanghai (CN); Weisin TAN, Shanghai (CN)

(21) Appl. No.: 19/021,335

(22) Filed: Jan. 15, 2025

(30) Foreign Application Priority Data
Jan. 18, 2024 (WO) PCT/CN2024/072987

(51) Int. Cl. H10H 29/856; H10H 29/49; H10H 29/80

(52) U.S. Cl. CPC H10H 29/856; H10H 29/49; H10H 29/962

(57) ABSTRACT

A micro LED display panel includes a micro LED array including a plurality of micro LEDs and a plurality of electrical connection structures disposed around the plurality of micro LEDs and electrically connected to the plurality of micro LEDs. A plurality of light propagation channels are formed between adjacent ones of the micro LEDs. Each light propagation channel includes at least one of a plurality of gaps defined between adjacent ones of the electrical connection structures. From a top view of the micro LED array, the light propagation channels are flexural.

### CROSS-REFERENCE TO RELATED APPLICATION

The present application claims the benefits of priority to International Patent Application No. PCT/CN2024/072987, filed Jan. 18, 2024, which is incorporated herein by reference in its entirety.

### TECHNICAL FIELD

The present disclosure generally relates to micro LED display technology, and more particularly, to a micro LED display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A multi-color micro LED display panel includes a micro LED array composed of multiple multi-color micro LEDs, which are conventionally referred to as multi-color pixels. It is advantageous to increase the density of the micro LEDs in the multi-color micro LED display, which requires reducing the size and space between the micro LEDs. However, when the spaces between the pixels reduces, light emitted from a single micro LED may propagate laterally to reach micro LEDs that are adjacent to the single micro LED, resulting in optical crosstalk between the micro LEDs.

### SUMMARY OF THE DISCLOSURE

Embodiments of the present disclosure provide a micro LED display panel. The micro LED display panel includes a micro LED array including a plurality of micro LEDs and a plurality of electrical connection structures disposed around the plurality of micro LEDs and electrically connected to the plurality of micro LEDs. A plurality of light propagation channels are formed between adjacent ones of the micro LEDs. Each light propagation channel includes at least one of a plurality of gaps defined between adjacent ones of the electrical connection structures. From a top view of the micro LED array, the light propagation channels are flexural.

Embodiments of the present disclosure also provide a micro LED display panel. The micro LED display panel includes a micro LED array including a plurality of micro LEDs and a plurality of electrical connection structures disposed around the plurality of micro LEDs and electrically connected to the plurality of micro LEDs. The plurality of electrical connection structures include a first electrical connection structure and a second electrical connection structure adjacent to each other. The first electrical connection structure includes a first side facing the second electrical connection structure. The second electrical connection structure includes a second side facing the first electrical connection structure. Both of the first side and the second side are nonlinear.

Embodiments of the present disclosure further provide a method for reducing optical crosstalk between light emitting units in a display panel. The display panel includes a plurality of light emitting units and a plurality of electrical connection structures disposed around the plurality of light emitting units and electrically connected to the plurality of light emitting units. The electrical connection structures are spaced apart from each other to define a plurality of gaps therebetween. The method includes reflecting light emitted by one of the light emitting units by at least a portion of one of the electrical connection structures disposed on a light propagation path of the light emitting unit.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 schematically illustrates a top view of a micro LED display panel according to an embodiment of the present disclosure.

FIG. 2 schematically illustrates a top view of a single micro LED and electrical connection structures around the single micro LED in a micro LED array of the embodiment shown in FIG. 1.

FIG. 3 schematically illustrates a cross-sectional view of the structure of FIG. 2 along section line a-a′.

FIG. 4 schematically illustrates a cross-sectional view of the structure of FIG. 2 along section line b-b′.

FIG. 5 schematically illustrates a cross-sectional view of the structure of FIG. 2 along section line c-c′ or section line d-d′.

FIG. 6A schematically illustrates a top view of a micro LED array according to an embodiment of the present disclosure.

FIG. 6B schematically illustrates an enlarged top view of the micro LED array of FIG. 6A.

FIG. 6C schematically illustrates a cross-sectional view of the structure of FIG. 6A along section line e-e′.

FIG. 6D schematically illustrates a cross-sectional view of the structure of FIG. 6A along section line f-f′.

FIG. 6E schematically illustrates a cross-sectional view of the structure of FIG. 6A along section line g-g′.

FIG. 7 schematically illustrates a top view of a micro LED array according to an embodiment of the present disclosure.

FIG. 8 schematically illustrates a top view of a micro LED array according to an embodiment of the present disclosure.

FIG. 9A schematically illustrates a top view of a micro LED array according to an embodiment of the present disclosure.

FIG. 9B schematically illustrates a top view of a micro LED array according to an embodiment of the present disclosure.

FIG. 9C schematically illustrates a top view of a micro LED array according to an embodiment of the present disclosure.

FIG. 10 schematically illustrates a top view of a micro LED array according to an embodiment of the present disclosure.

FIG. 11 schematically illustrates a top view of a micro LED array according to an embodiment of the present disclosure.

FIG. 12 schematically illustrates a top view of a single micro LED and electrical connection structures around the single micro LED in the micro LED array of FIG. 11.

FIG. 13 schematically illustrates a cross-sectional view of the structure of FIG. 11 along section line i-i′.

FIG. 14 schematically illustrates a cross-sectional view of the structure of FIG. 11 along section line j-j′.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

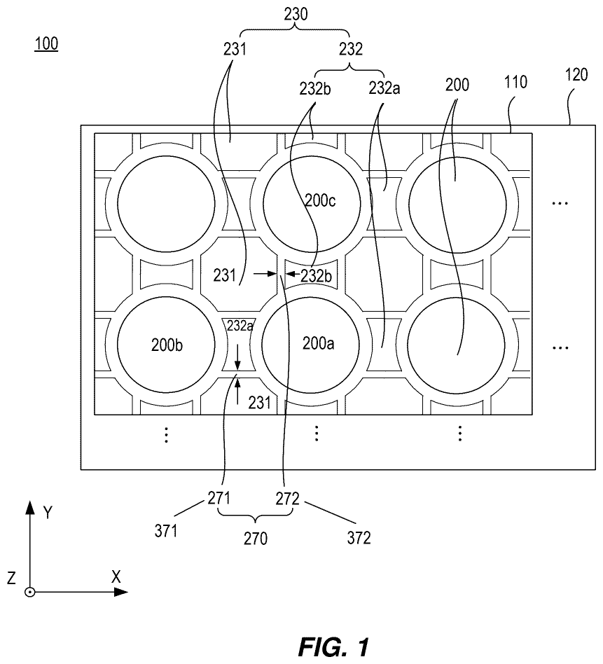

FIG. 1 schematically illustrates a top view of a micro LED display panel 100 according to an embodiment of the present disclosure. Referring to FIG. 1, micro LED display panel 100 includes a micro LED array 110 including a plurality of micro LEDs 200 and a plurality of electrical connection structures 230 disposed around the plurality of micro LEDs 200, and a driving backplane 120. Micro LED array 110 is disposed on a top surface of driving backplane 120 and forms an image display area. Driving backplane 120 is disposed at a backside of micro LED array 110. An area of driving backplane 120 where micro LED array 110 is not disposed is a non-functional area.

Driving backplane 120 is configured to control the plurality of micro LEDs 200. In some embodiments, driving backplane 120 may be a TFT (Thin Film Transistor) board or an IC (Integrated Circuit) board.

In micro LED array 110, the plurality of micro LEDs 200 are arranged in an array on the top surface of driving backplane 120.

In the following description and as illustrated in the drawings, a direction along which the plurality of micro LEDs 200 are arranged along the top surface of driving backplane 120 is an X-direction. A direction along the top surface of driving backplane 120 and perpendicular to the X-direction is a Y-direction. The top surface of driving backplane 120 is disposed in an X-Y plane. A direction perpendicular to the X-Y plane is a Z-direction.

Electrical connection structures 230 are electrically connected to the micro LEDs 200 for providing electrical power to the micro LEDs 200. Electrical connection structures 230 may be made of conductive and non-transparent metal, such as, for example, Al, Au, Rh, Ag, Cr, Ti, Pt, Sn, Cu, etc, or a combination of two or more of those metal materials. Electrical connection structures 230 not only provide electrical power to micro LEDs 200, but also reflect the light emitted from micro LEDs 200.

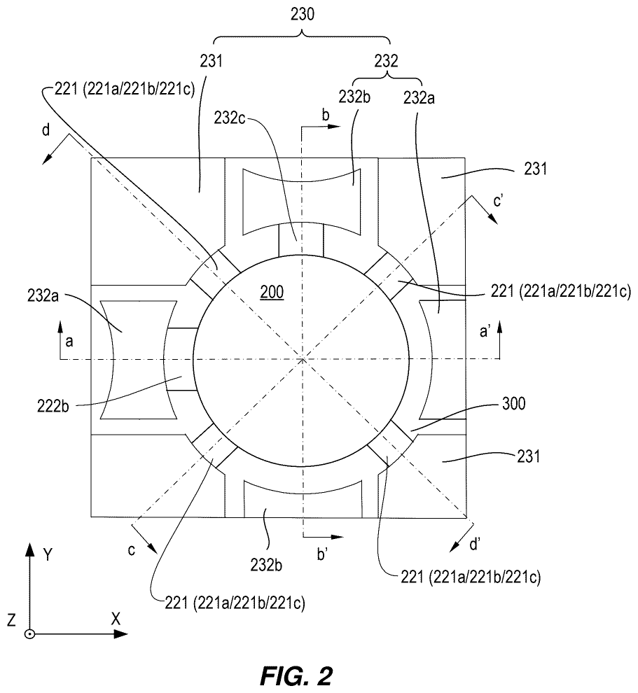

Electrical connection structures 230 include a plurality of top electrical connection structures 231 and plurality of bottom electrical connection structures 232. As will be further described in detail with reference to FIGS. 2-5, each one of the plurality of micro LEDs 200 comprises two or more light emitting mesas which are disposed in a vertical direction (the Z-direction) from top to bottom. Top electrical connection structures 231 are electrically connected to a top of each one of the two or more light emitting mesas. Each of bottom electrical connection structures 232 is electrically connected to a bottom of one of the two or more light emitting mesas.

In the embodiment illustrated in FIG. 1, bottom electrical connection structures 232 further include a plurality of first bottom electrical connection structure 232a disposed between adjacent micro LEDs 200 arranged along the X-direction, and a plurality of second bottom electrical connection structures 232b disposed between adjacent micro LEDs 200 arranged along the Y-direction. In some alternative embodiments, first bottom electrical connection structure 232a may be disposed between adjacent micro LEDs 200 arranged along the Y-direction, and second bottom electrical connection structures 232b may be disposed between adjacent micro LEDs 200 arranged along the X-direction

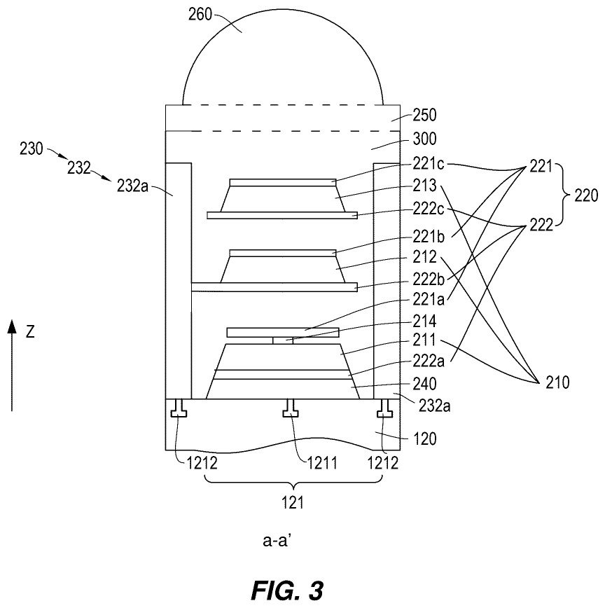

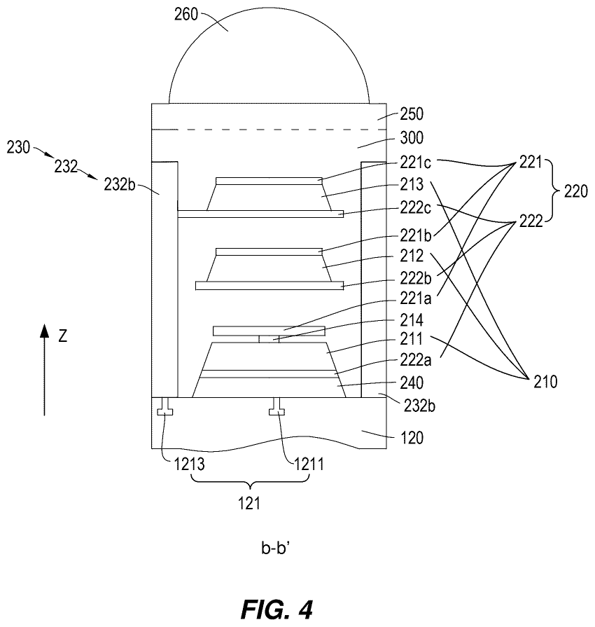

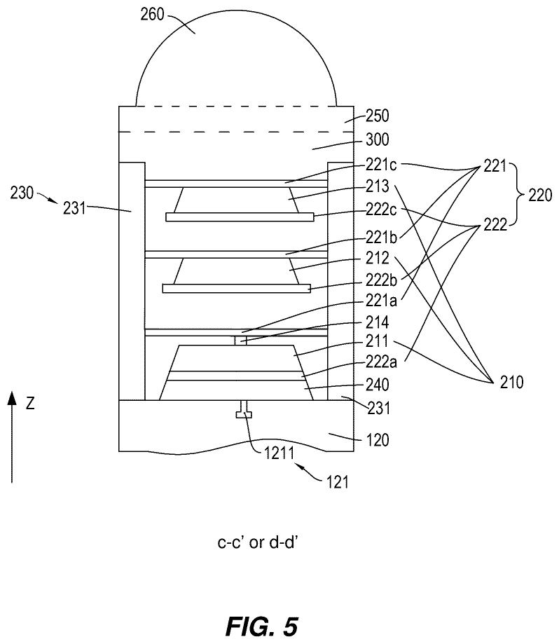

FIG. 2 schematically illustrates a top view of a single micro LED 200 and electrical connection structures 230 around the single micro LED 200 in micro LED array 110 of the embodiment of FIG. 1. FIG. 3 schematically illustrates a cross-sectional view of the structure of FIG. 2 along a section line a-a′ in FIG. 2. FIG. 4 schematically illustrates a cross-sectional view of the structure of FIG. 2 along a section line b-b′ in FIG. 2. FIG. 5 schematically illustrates a cross-sectional view of the structure of FIG. 2 along a section line c-c′ or a section line d-d′ in FIG. 2.

Referring to FIGS. 3 to 5, micro LED 200 includes at least two light emitting mesas 210 stacked from top to bottom along a vertical direction (the Z-direction) and conductive layers 220 located on top and bottom sides of each light emitting mesa 210. Conductive layers 220 include a top conductive layer 221 disposed above each light emitting mesa 210 and a bottom conductive layer 222 disposed below each light emitting mesa 210. For each light emitting mesa 210, top conductive layer 221 is electrically connected to a top surface of the light emitting mesa 210, and bottom conductive layer 222 is electrically connected to a bottom surface of the light emitting mesa 210. Conductive layers 220 are used to provide electrical power to the corresponding light emitting mesas 210.

In the embodiment illustrated in FIGS. 3-5, the at least two light emitting mesas 210 include a first light emitting mesa 211, a second light emitting mesa 212, and a third light emitting mesa 213 that are stacked along a vertical direction (the Z-direction) from bottom to top, with first light emitting mesa 211 disposed at the bottom. In some embodiments, the number of the light emitting mesas 210 may be two or four or more than four. In some embodiments, first light emitting mesa 211 emits red light, second light emitting mesa 212 emits green light, and third light emitting mesa 213 emits blue light. In some embodiments, first light emitting mesa 211 emits red light, second light emitting mesa 212 emits blue light, and third light emitting mesa 213 emits green light. In some embodiments, the bottommost light emitting mesa emits red light, and the topmost light emitting mesa emits green light. In some embodiments, different light emitting mesas 210 in the same micro LED 200 emit light of the same color. For example, first light emitting mesa 211, second light emitting mesa 212, and third light emitting mesa 213 in the same micro LED 200 all emit blue light, or all emit green light or red light. Among the at least two light emitting mesas 210 stacked along the vertical direction, adjacent light emitting mesas 210 are spaced apart from each other in the vertical direction. In some embodiments, the distance between adjacent light emitting mesas 210 along the vertical direction is the same. In some embodiments, the distance between adjacent light emitting mesas 210 along the vertical direction may be set to be different as needed. In some embodiments, both the top surface and the bottom surface of each light emitting mesa 210 are circular, and the diameter of the top surface of the light emitting mesa 210 is smaller than the diameter of the bottom surface of the light emitting mesa 210. For example, in the embodiment illustrated in FIGS. 3-5, for each of first to third light emitting mesas 211, 212, and 213, the diameter of the top surface is smaller than the diameter of the bottom surface. In some embodiments, the top and bottom surfaces of the light emitting mesa 210 may be non-circular, such as square, oval, etc. In some embodiments, the area of the top surface of the light emitting mesa 210 is less than the area of the bottom surface.

In some embodiments, at least two light emitting mesas 210 are coaxially disposed. In other words, the projections of light emitting mesas 210 along the vertical direction overlap. In some embodiments, the sizes of the light emitting mesa 210 may be different, and the projections of light emitting mesas 210 along the vertical direction may partially overlap.

Referring to FIGS. 2 to 5, electrical connection structures 230 are disposed around micro LEDs 200. Each electrical connection structure 230 is electrical power connected to at least one of conductive layers 220 of micro LEDs 200 for providing electricity to light emitting mesa 210. Electrical connection structures 230 include at least one top electrical connection structure 231 and at least one bottom electrical connection structure 232. The at least one top electrical connection structure 231 is electrically connected to top conductive layer 221 of each light emitting mesa 210. Each bottom electrical connection structure 232 is electrically connected to bottom conductive layer 222 of one of light emitting mesas 210. The bottom of top electrical connection structure 231 contacts driving backplane 120 but is not directly electrically connected to driving backplane 120. Top electrical connection structure 231 may electrically connect top conductive layer 221 with a negative electrode of an external power supply. The bottom of each bottom electrical connection structure 232 contacts driving backplane 120 and is electrically connected to driving backplane 120. Each bottom electrical connection structure 232 may electrically connect bottom conductive layer 222 with a positive electrode of the external power supply.

Referring to FIG. 2, bottom electrical connection structure 232 includes at least one first bottom electrical connection structure 232a and at least one second bottom electrical connection structure 232b. The at least one first bottom electrical connection structure 232a is located along the direction of section line a-a′ in FIG. 2, and the at least one second bottom electrical connection structure 232b is located along the direction of section line b-b′ in FIG. 2. Top electrical connection structure 231 is located along the direction of section line c-c′ and line d-d′ in FIG. 2.

Referring to FIGS. 3 to 5, bottom conductive layer 222 includes a first bottom conductive layer 222a, a second bottom conductive layer 222b, and a third bottom conductive layer 222c. First bottom conductive layer 222a is located at the bottom of first light emitting mesa 211, second bottom conductive layer 222b is located at the bottom of second light emitting mesa 212, and third bottom conductive layer 222c is located at the bottom of third light emitting mesa 213. Top conductive layer 221 includes a first top conductive layer 221a, a second top conductive layer 221b, and a third top conductive layer 221c. First top conductive layer 221a is located on the top of first light emitting mesa 211, second top conductive layer 221b is located on the top of second light emitting mesa 212, and third top conductive layer 221c is located on the top of third light emitting mesa 213.

Top electrical connection structure 231 is electrically connected to all of top conductive layers 221 (i.e., first top conductive layer 221a, second top conductive layer 221b, and third top conductive layer 221c) of each one of micro LEDs 200. Bottom electrical connection structure 232 is connected to one of the bottom conductive layers 222 (i.e., first bottom conductive layer 222a, second bottom conductive layer 222b, or third bottom conductive layer 222c) of one of micro LEDs 200.

In the embodiment illustrated in FIG. 2, the number of top electrical connection structures 231 is four, two of which being arranged along the direction of section line c-c′, the other two being arranged along the direction of section line d-d′. The four top electrical connection structures 231 are electrically connected to top conductive layers 221 (first top conductive layer 221a, second top conductive layer 221b, and third top conductive layer 221c) of all light emitting mesas 210 (first light emitting mesa 211, second light emitting mesa 212, and third light emitting mesa 213) of micro LED 200. Electrical connection structures 230 (including the four top electrical connection structures 231, first bottom electrical connection structure 232a, and second bottom electrical connection structure 232b) are spaced apart from each other around micro LED 200, and the gaps between adjacent electrical connection structures 230 are filled with an insulating medium 300.

Referring to FIGS. 2 to 5, some of conductive layers 220 extend towards and contact corresponding electrical connection structures 230 to make electrical connection to the corresponding electrical connection structures 230.

Specifically, as illustrated in FIGS. 2 and 5, all of top conductive layers 221 (221a, 221b, 221b) of light emitting mesas 210 (211, 212, 213) extend towards and contact the top electrical connection structures 231 disposed around micro LED 200, to be electrically connected to top electrical connection structure 231.

As illustrated in FIGS. 2 and 3, second bottom conductive layer 222b of second light emitting mesa 212 extends towards and contacts one of first bottom electrical connection structures 232a (i.e., the left-side first bottom electrical connection structure 232a in FIG. 3), to be electrically connected to the one of first bottom electrical connection structures 232a. The right-side first bottom electrical connection structure 232a in FIG. 3 is connected to an adjacent micro LED.

As illustrated in FIGS. 2 and 4, third bottom conductive layer 222c of third light emitting mesa 213 extends toward and contacts one of second bottom electrical connection structures 232b (i.e., the left-side second bottom electrical connection structures 232b in FIG. 4), to be electrically connected to the one of second bottom electrical connection structures 232b. The right-side second bottom electrical connection structure 232a in FIG. 4 is connected to an adjacent micro LED.

In the embodiment illustrated in FIGS. 2 to 5, the side surfaces of electrical connection structures 230 contact the end surfaces of the corresponding conductive layers 220. In some alternative embodiments, electrical connection structures 230 may further include protrusions extending towards and contacting the corresponding conductive layers 220. The end surfaces of the protrusions may contact the end surfaces the corresponding conductive layers 220. Alternatively, the protrusions may overlap and contact end portions of the corresponding conductive layers 220. FIGS. 2 to 5 only illustrate one example of the shapes of the extensions of conductive layers 220, but the extensions of conductive layers 220 may have various shapes and arrangements, that are not limited to the example illustrated in FIGS. 2 to 5. In addition, for the sake of abbreviation, the top views of the extensions of conductive layers 220 are only illustrated in FIG. 2, but not in FIG. 1.

Referring to FIG. 1, in some embodiments, the top electrical connection structures 231 of adjacent micro LEDs 200 are electrically connected to each other, and the bottom electrical connection structures 232 of adjacent micro LEDs 200 are insulated from each other.

Referring to FIGS. 3 to 5, in some embodiments, the spaces between adjacent light emitting mesas 210 and between electrical connection structures 230 and light emitting mesas 210 are filled with insulating medium 300. Insulating medium 300 is transparent. In some embodiments, the material of insulating medium 300 may include includes one or a combination of SiO₂, SiON, Al₂O₃, and SiN.

Referring to FIGS. 3 to 5, micro LED 200 further includes a bottom connection mesa 240, which is located between the bottommost light emitting mesa 210 (i.e., first light emitting mesa 211) and driving backplane 120, and is electrically connected to both driving backplane 120 and the bottommost light emitting mesa 210 (i.e., first light emitting mesa 211). Micro LED 200 further includes a top connection mesa 214 located between first light emitting mesa 211 and first top conductive layer 221a and electrically connected to both first light emitting mesa 211 and first top conductive layer 221a. The material of bottom connection mesa 240 and top connection mesa 214 is metal, including one or more of Al, Au, Rh, Ag, Cr, Ti, Pt, Sn, Cu, AuSn, TiW, etc. In some embodiments, both the top surface and the bottom surface of light emitting mesas 210 (mesas 211, 212, and 213) are circular, and the diameter of the top surface of each light emitting mesa 210 is smaller than the diameter of the bottom surface. In such embodiments, the top surface of bottom connection mesa 240 is also circular, and the diameter of the top surface of bottom connection mesa 240 is the same as the diameter of the bottom surface of the bottommost light emitting mesa 210 (i.e., the first light emitting mesa 211), and the diameter of the top surface of bottom connection mesa 240 is smaller than the diameter of the bottom surface of bottom connection mesa 240. The first bottom conductive layer 222a is disposed between the bottom connection mesa 240 and the first light emitting mesa 211, and may form an ohmic contact layer between bottom connection mesa 240 and first light emitting mesa 211. First bottom conductive layer 222a and bottom connection mesa 240 can form an omni-directional mirror structure (Omni-Directional Reflector (ODR)) with high reflection efficiency.

Conductive layers 220 are transparent. Each one of conductive layers 220 may be one of, or a combination of one or more of, TCO (Transparent Conductive Oxide) films such as an ITO (Indium Tin Oxide) film, an AZO (Antimony doped Zinc Oxide) film, an ATO (Antimony doped Tin Oxide) film, and a FTO (Fluorine) doped Tin Oxide).

Referring to FIGS. 3 to 5, micro LED 200 further includes a top insulating dielectric layer 250. Top insulating dielectric layer 250 continuously covers the top surface of micro LED array 110. Top insulating dielectric layer 250 is transparent, and the material of top insulating dielectric layer 250 is one or a combination of SiO₂, SiN, SiON, or Al₂O₃.

Referring to FIGS. 3 to 5, micro LED 200 further includes a microlens 260. Microlens 260 is located above top insulating dielectric layer 250, and covers a pixel area of micro LED 200. A bottom diameter of microlens 260 is larger than the maximum diameter of light emitting mesa 210. The thickness of microlens 260 is less than or equal to 10 μm. In some embodiments, the material of microlens 260 is selected from silicon dioxide, photoresist, and the like.

Referring to FIGS. 1 to 5, in some embodiments, the thickness of light emitting mesa 210 may range, for example, from 0.3 μm to 3.5 μm, and the bottom diameter of light emitting mesa 210 may range, for example, from 0.5 μm to 50 μm. The thickness of micro LED 200 may range, for example, from 1 μm to 10 μm, and the diameter of micro LED 200 may range, for example, from 2 μm to 200 μm. The size of micro LED display panel 100 may range, for example, from 500 μm to 50000 μm. The resolution of micro LED array 110 in micro LED display panel 100 may, for example, be one of 320×240, 640×480, 1920×1080, or 2560×1440.

Referring to FIGS. 3 to 5, driving backplane 120 includes a solder joint group 121 corresponding to micro LED 200. Solder joint group 121 includes a first solder joint 1211, a second solder joint 1212, and a third solder joint 1213. First solder joint 1211 corresponds to and is electrically connected to bottom connection mesa 240. Second solder joint 1212 corresponds to and is electrically connected to first bottom electrical connection structure 232a. Third solder joint 1213 corresponds to and is electrically connected to second bottom electrical connection structure 232b.

Referring back to FIG. 1, electrical connection structures 230 are disposed around each micro LED 200, and gaps 270 are defined between adjacent electrical connection structures 230 and filled with insulating medium 300 (shown in FIGS. 3-5). Each of gaps 270 is straight and extends along the direction in which micro LEDs 200 are arranged, thereby forming a light propagation channel that allows light emitted from each micro LEDs 200 to propagate through laterally. As a result, optical crosstalk between adjacent micro LEDs 200 may undesirably arise. For example, as illustrated in FIG. 1, gaps 270 includes at least a first gap 271 between a top electrical connection structure 231 and a first bottom electrical connection structure 232a that are adjacent to each other and arranged along the Y-direction, and a second gap 272 between a top electrical connection structure 231 and a second bottom electrical connection structure 232b that are adjacent to each other and arranged along the X-direction. First gap 271 is straight and extends along the X-direction, which is parallel to the direction along which adjacent micro LEDs 200a and 200b are arranged. Therefore, first gap 271 forms a light propagation channel 371 through which light emitted from micro LED 200a may propagate and reach micro LED 200b, and light emitted from micro LED 200b may propagate and reach micro LED 200a. Similarly, second gap 272 is straight and extends along the Y-direction, which is parallel to the direction along which adjacent micro LEDs 200a and 200c are arranged. Therefore, second gap 272 forms a light propagation channel 372 through which light emitted from micro LED 200a may pass and reach micro LED 200c, and light emitted from micro LED 200c may pass and reach micro LED 200a. Thus, optical crosstalk between adjacent micro LEDs 200 may arise from the lateral light propagating through the straight gaps 270 between adjacent electrical connection structures 230, reducing luminous efficiency of micro LED display panel 100.

In order to reduce the optical crosstalk between adjacent micro LEDs 200 resulting from the straight gaps 270 between adjacent electrical connection structures 230, according to some of the embodiments of the present disclosure, the light propagation channels formed between adjacent micro LEDs are flexural in a top view of a micro LED array. As used in the present disclosure and in the claims, the term “flexural” means that each light propagation channel is bending, flexed, or curved, and is nonlinear, i.e., not in a straight line. The term “adjacent” means that there is no other object between two adjacent objects except for insulating medium 300. The light propagation channels may include one or more gaps formed between adjacent electrical connection structures 230. In some embodiments, the sides of the adjacent electrical connection structures 230 that face each other, are also configured to be flexural, i.e., bending, flexed, or curved, and are substantially parallel to each other. As a result, gaps 270 defined between adjacent ones of electrical connection structures 230 are flexural. For example, as further explained below, each top electrical connection structure 231 is formed to have a “plus” cross section and each bottom electrical connection structure 232 is formed with four sides (as a quadrilateral). As a result, each gap 270 may have at least two sections extending along directions that are not parallel to each other, and therefore each gap 270 may be flexural. As another example, each gap 270 may be curved, or may include at least one curved section. Therefore, the light propagation channels including at least one of the gaps 270 may be flexural.

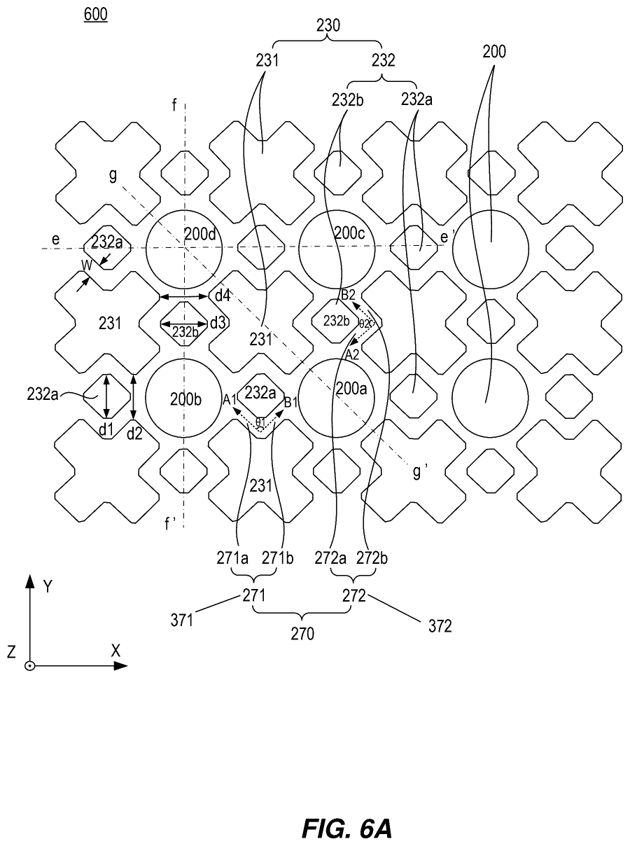

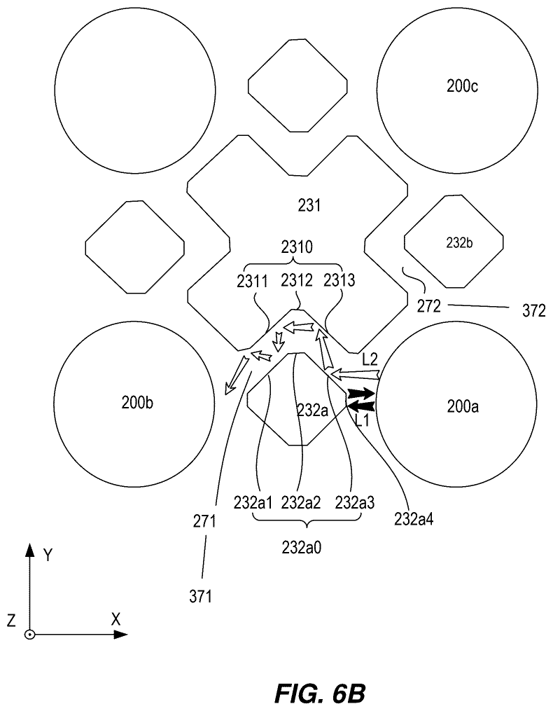

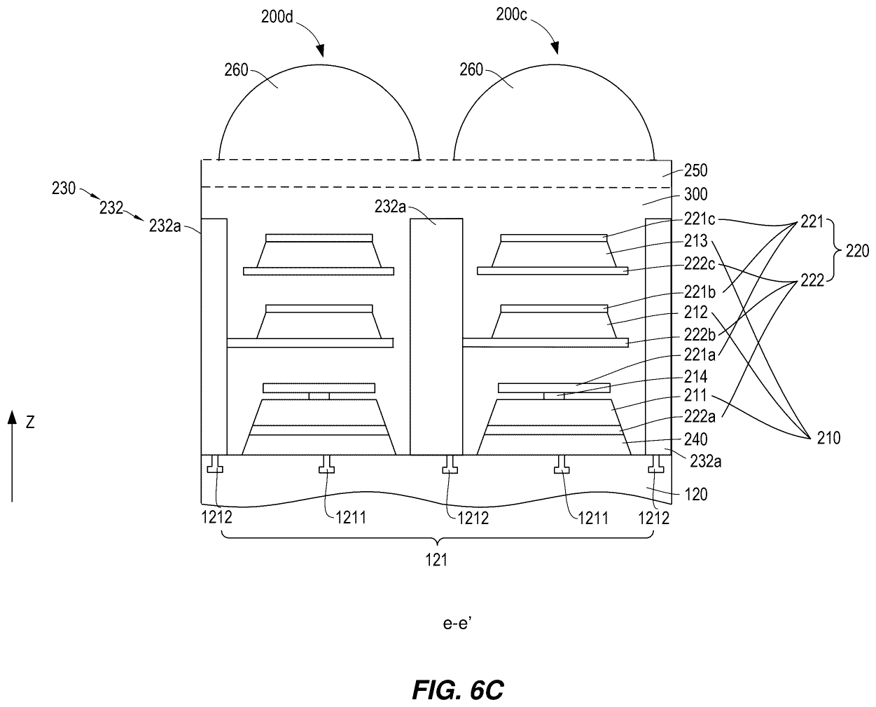

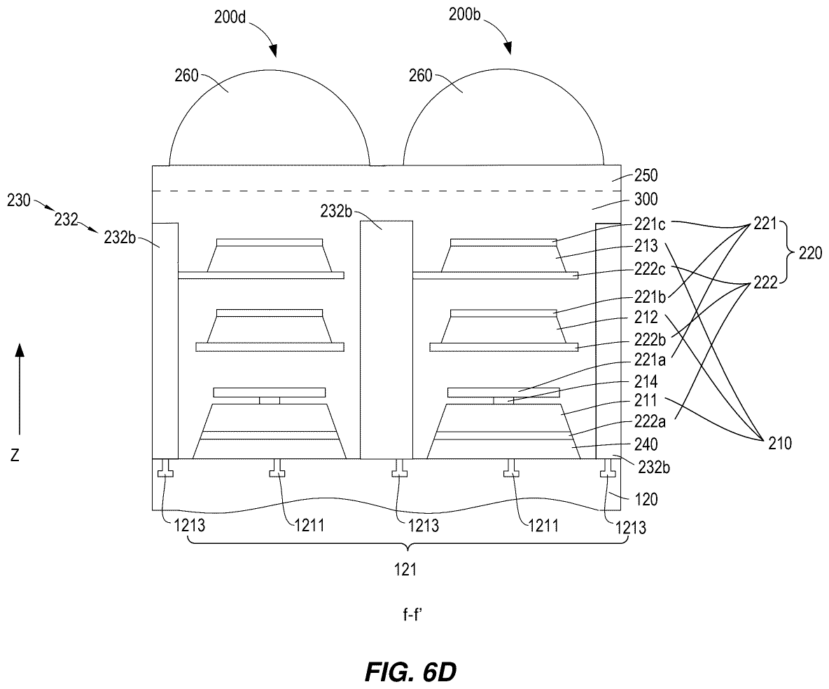

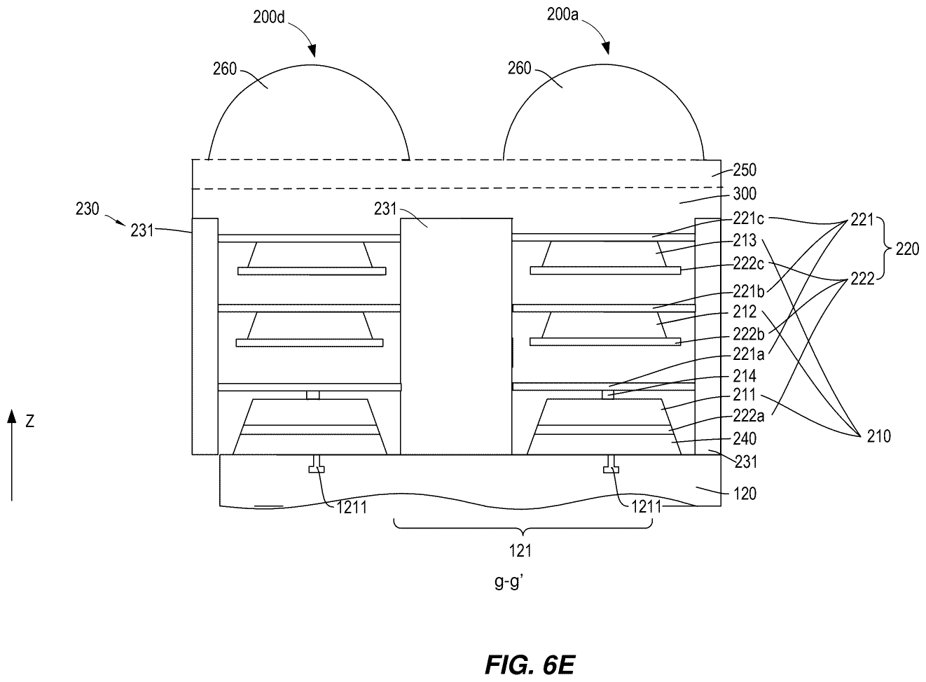

FIG. 6A schematically illustrates a top view of a micro LED array 600 according to an embodiment of the present disclosure. FIG. 6B schematically illustrates an enlarged top view of the micro LED array of FIG. 6A. FIG. 6C schematically illustrates a cross-sectional view of the structure of FIG. 6A along section line e-e′. FIG. 6D schematically illustrates a cross-sectional view of the structure of FIG. 6A along section line f-f′. FIG. 6E schematically illustrates a cross-sectional view of the structure of FIG. 6A along section line g-g′.

As illustrated in FIG. 6A, micro LED array 600 includes a plurality of micro LEDs 200 and a plurality of electrical connection structures 230 disposed around the plurality of micro LEDs 200 and electrically connected to the plurality of micro LEDs 200. The plurality of electrical connection structures 230 include a plurality of top electrical connection structures 231 and a plurality of bottom electrical connection structures 232, which include a plurality of first bottom electrical connection structures 232a and a plurality of second bottom electrical connection structures 232b. The plurality of first bottom electrical connection structures 232a and the plurality of micro LEDs 200 are alternately arranged along the X-direction. The plurality of second bottom electrical connection structures 232b and the plurality of micro LEDs 200 are alternately arranged along the Y-direction. The plurality of top electrical connection structures 231 and the plurality of first bottom electrical connection structures 232a are alternately arranged along the Y-direction. The plurality of top electrical connection structures 231 and the plurality of second bottom electrical connection structures 232b are alternately arranged along the X-direction. A plurality of light propagation channels 371 and 372 are formed between adjacent ones of micro LEDs 200. A plurality of gaps 270 are defined between adjacent ones of electrical connection structures 230. Each light propagation channel 371 or 372 includes at least one of gaps 270. As shown in the top view of micro LED array 600 in FIG. 6A, light propagation channels 371 and 372 are flexural. Each top electrical connection structure 231 is formed to have a “plus” cross section and each bottom electrical connection structure 232 is formed with four sides (as a quadrilateral) each being substantially parallel to a side of an adjacent top electrical connection structure 231. As a result, each of gaps 270 defined between the adjacent ones of electrical connection structures 230 is flexural, and includes two sections extending along directions that are not parallel to each other, i.e., that cross each other. Each gap 270 forms a light propagation channel which is flexural. Each of the flexural light propagation channels 270 reduces the intensity of the light emitted from one of micro LEDs 200 and propagating through the light propagation channel to its adjacent micro LEDs 200. Specifically, as illustrated in FIG. 6A, gaps 270 includes at least a first gap 271 between a top electrical connection structure 231 and a first bottom electrical connection structure 232a that are adjacent to each other and arranged along the Y-direction, and a second gap 272 between a top electrical connection structure 231 and a second bottom electrical connection structure 232b that are adjacent to each other and arranged along the X-direction. First gap 271 constitutes a light propagation channel 371 between micro LEDs 200a and 200b. First gap 271 includes a first section 271a extending along a first direction A1, and a second section 271b extending along a second direction B1. First direction A1 and second direction B1 are not parallel to each other. In other words, first direction A1 crosses second direction B1. An angle θ1 between first direction A1 and second direction B1 is more than 0° and less than 180°. Similarly, second gap 272 constitutes a light propagation channel 372 between micro LEDs 200a and 200c. Second gap 272 includes a first section 272a extending along a first direction A2, and a second section 272b extending along a second direction B2. First direction A2 and second direction B2 are not parallel to each other. An angle θ2 between first direction A2 and second direction B2 is more than 0° and less than 180°.

FIG. 6B schematically illustrates an enlarged top view of micro LED array 600 of FIG. 6A. As illustrated in FIG. 6B, top electrical connection structure 231 includes a side 2310 facing first bottom electrical connection structure 232a, and first bottom electrical connection structure 232a includes a side 232a0 facing side 2310 of top electrical connection structure 231. Both of side 2310 of top electrical connection structure 231 and side 232a0 of first bottom electrical connection structure 232a are nonlinear, i.e., flexural. Side 2310 of top electrical connection structure 231 include sections 2311, 2312, and 2313 extending along different directions. At least one of sections 2311, 2312, and 2313 is not parallel to the X-direction. Side 232a0 of first bottom electrical connection structure 232a include sections 232a1, 232a2, and 232a3 extending along different directions. At least one of sections 232a1, 232a2, and 232a3 is not parallel to the X-direction. First gap 271 is defined between side 2310 of top electrical connection structure 231 and side 232a0 of first bottom electrical connection structure 232a. Side 2310 of top electrical connection structure 231 and side 232a0 of first bottom electrical connection structure 232a are in conformance with each other. In other words, the sizes and angles of sections 2311, 2312, and 2313 of side 2310 of top electrical connection structure 231 correspond to the sizes and angles of sections 232a1, 232a2, and 232a3 of side 232a0 of first bottom electrical connection structure 232a. Side 232a0 of first bottom electrical connection structure 232a defines a protrusion that protrudes towards first bottom electrical connection structure 232a. Side 2310 of top electrical connection structure 231 defines a recess that is recessed for accommodating the protrusion defined by side 232a0 of first bottom electrical connection structure 232a.

As indicated by solid arrow “L1” in FIG. 6B, a portion of light L1 emitted from micro LED 200a along the X-direction reaches a side 232a4 of first bottom electrical connection structure 232a that faces micro LED 200a, and the portion of light L1 is reflected back towards micro LED 200a by side 232a4 of first bottom electrical connection structure 232a. As indicated by hollow arrows “L2” in FIG. 6B, a portion of light L2 emitted from micro LED 200a enters light propagation channel 371 formed by first gap 271 defined between first bottom electrical connection structure 232a and top electrical connection structure 231, and is reflected multiple times by the sidewalls of first gap 271 formed by side 2310 of top electrical connection structure 231 and side 232a0 of first bottom electrical connection structure 232a before the light reaches adjacent micro LED 200b. Thus, the intensity of light L2 that propagates through light propagation channel 371 and reaches adjacent micro LED 200b is significantly reduced after the multiple reflections. As a result, the flexural light propagation channel 371 including first gap 271 defined between first bottom electrical connection structure 232a and top electrical connection structure 231 significantly reduces the optical crosstalk between micro LEDs 200a and 200b arranged long the X-direction. In a similar manner, the flexural light propagation channel 372 including flexural second gap 272 defined between second bottom electrical connection structure 232b and top electrical connection structure 231 may significantly reduce the optical crosstalk between micro LEDs 200a and 200c arranged long the Y-direction. As a result, luminous efficiency of micro LED array 110 may be improved.

FIG. 6C schematically illustrates a cross-sectional view of the structure of FIG. 6A along section line e-e′. FIG. 6D schematically illustrates a cross-sectional view of the structure of FIG. 6A along section line f-f′. FIG. 6E schematically illustrates a cross-sectional view of the structure of FIG. 6A along section line g-g′. Each micro LED 200 in FIGS. 6C-6E has a structure similar to the micro LED 200 in FIGS. 3-5, and therefore detailed descriptions thereof are not repeated. As illustrated in FIG. 6C, each first bottom electrical connection structure 232a is electrically connected to second bottom conductive layer 222b of micro LED 200. As illustrated in FIG. 6D, each second bottom electrical connection structure 232b is electrically connected to third bottom conductive layer 222c of micro LED 200. As illustrated in FIG. 6E, each top electrical connection structure 231 is electrically connected to first top conductive layer 221a, second top conductive layer 221b, and third top conductive layer 221c of all micro LEDs 200.

Referring back to FIG. 6A (none of FIGS. 6A-6E are to scale), a width W of each one of first and second gaps 271 and 272 may range from 50 nm to 2000 nm. The smaller the width of the sections of the gaps, the better light isolation effect the gaps may provide. A largest dimension d1 of first bottom electrical connection structure 232a along the Y-direction is equal to or greater than a shortest distance d2 between adjacent ones of top electrical connection structures 231 along the Y-direction. A dimension d3 of second bottom electrical connection structure 232b along the X-direction is equal to or greater than a shortest distance d4 between two adjacent top electrical connection structure 231 along the X-direction.

In the embodiment illustrated in FIGS. 6A-6E, each of gaps 270 (including first and second gaps 271 and 272) includes two sections, and each section extends along a direction crossing the direction along which adjacent micro LEDs 200 are arranged. In some alternative embodiments, each gap may include more than two sections, and at least one of the sections extends along a direction crossing the direction along which adjacent micro LEDs 200 are arranged.

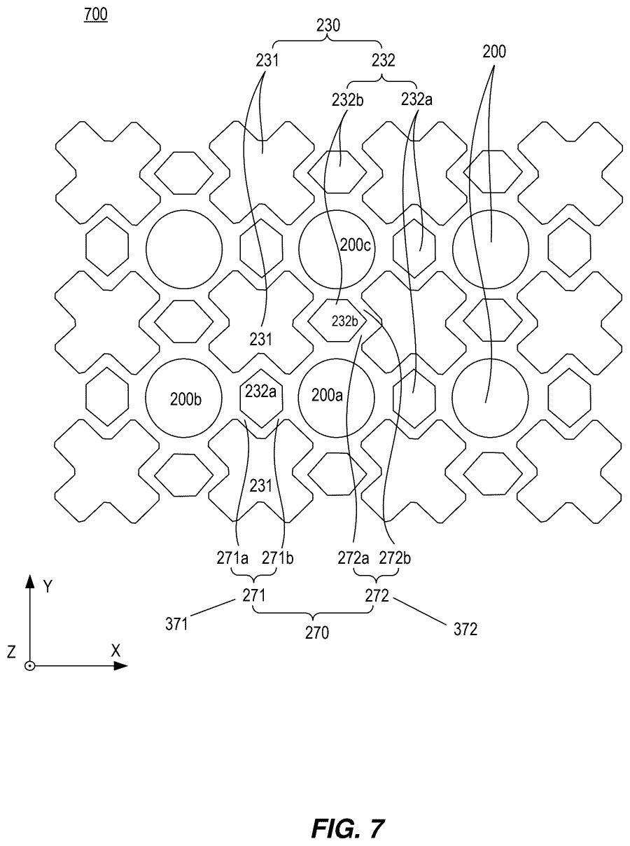

In the embodiment illustrated in FIGS. 6A-6E, as noted above, each of bottom electrical connection structures 232 is formed with four sides (as a quadrilateral). In some alternative embodiments, each of bottom electrical connection structures 232 may be formed with greater or fewer than four sides, while each of top electrical connection structures 231 is formed to have the “plus” cross section. FIG. 7 schematically illustrates a top view of a micro LED array 700 according to such an embodiment.

As illustrated in FIG. 7, each of bottom electrical connection structures 232 (including first and second bottom electrical connection structures 232a and 232b) is formed with six sides (as a hexagon). Two adjacent sides of bottom electrical connection structures 232 are substantially parallel to two sides of an adjacent top electrical connection structure 231 having the “plus” cross section, thereby defining gaps 270 each being nonlinear and including two sections that cross each other. Gaps 270 includes first gaps 271 each defined between a top electrical connection structure 231 and a first bottom electrical connection structure 232a that are adjacent to each other along the Y-direction, and second gaps 272 each defined between a top electrical connection structure 231 and a second bottom electrical connection structure 232b that are adjacent to each other along the X-direction. First gaps 271 and second gaps 272 are nonlinear, i.e., flexural. Accordingly, each first gap 271 forms a flexural light propagation channel 371 between adjacent micro LEDs 200 arranged along the X-direction, and each second gap 272 forms a flexural light propagation channel 372 between adjacent micro LEDs 200 arranged along the Y-direction. Except for the shapes of bottom electrical connection structures 232, the other elements of micro LED array 700 illustrated in FIG. 7, and the dimensions thereof, are the same as the elements of micro LED array 600 illustrated in FIGS. 6A and 6B, and therefore detailed descriptions of these elements are not repeated.

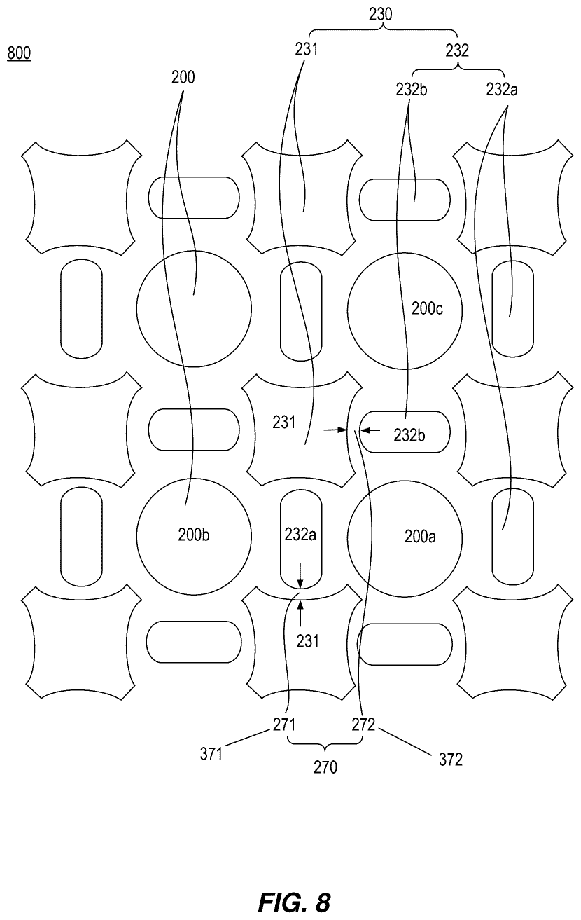

In the embodiment illustrated in FIGS. 6A-6E and 7, each of gaps 270 (including first and second gaps 271 and 272) includes sections that are straight. In some alternative embodiments, each of gaps 270 may include at least one section that is curved, or each of gaps 270 may be curved. FIG. 8 schematically illustrates a top view of a micro LED array 800 according to such an embodiment.

As illustrated in FIG. 8, each top electrical connection structure 231 is formed to be generally square with four concave sides, and each bottom electrical connection structure 232 is formed to be generally rectangular with convex sides facing the adjacent top electrical connection structures 231. As a result, each of gaps 270 (including first and second gaps 271 and 272) between top electrical connection structures 231 and bottom electrical connection structures 232 is curved, i.e., flexural. Therefore, light propagation channels 371 and 372 including first and second gaps 271 and 272, respectfully, are flexural. The light emitted from micro LED 200a and entering the flexural light propagation channels 371 and 372 is reflected multiple times by the curved sidewalls of the curved gaps 270 before the light reaches the adjacent micro LED 200b or 200c, and thus the intensity of the light that reaches the adjacent micro LED 200b or 200c is significantly reduced by the multiple reflections in the curved gaps 270. Thus, the curved gaps 270 reduces optical crosstalk between adjacent micro LEDs 200.

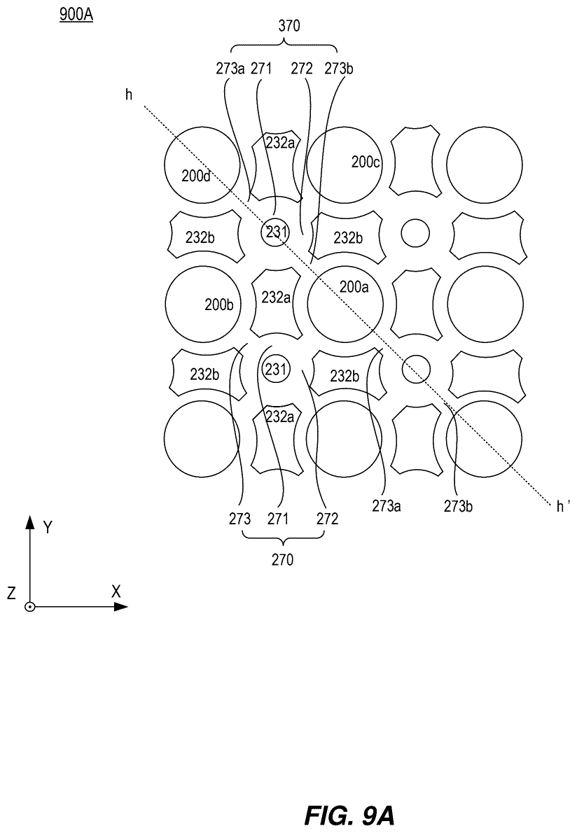

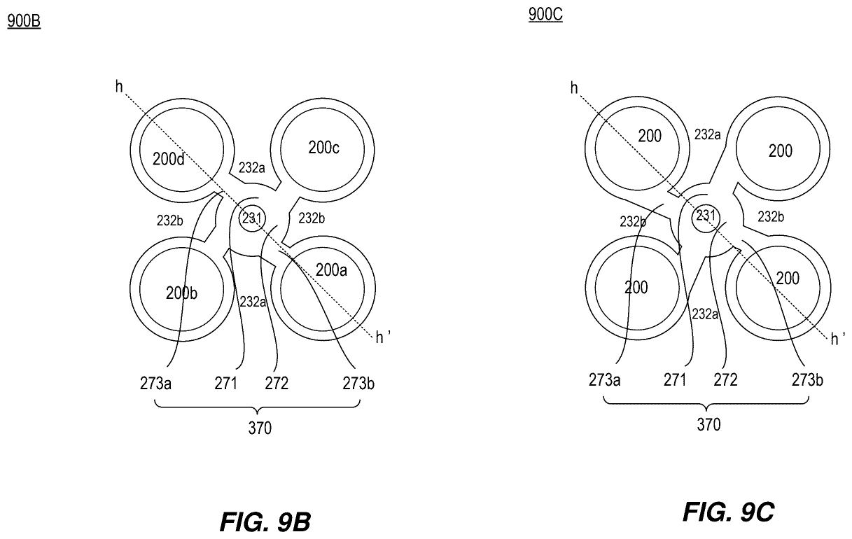

FIG. 9A schematically illustrates a top view of a micro LED array 900A according to another embodiment of the present disclosure. As illustrated in FIG. 9A, each top electrical connection structure 231 is formed to have a circular cross section having convex sides facing the adjacent bottom electrical connection structures 232, and each bottom electrical connection structure 232 is formed to have an irregular shape that is generally rectangular with all four sides partly concave. Two of the four concave sides of each bottom electrical connection structure 232 faces adjacent micro LEDs 200, and the curvatures of these two sides are generally similar to the curvatures of the adjacent sides of the micro LEDs 200 that face the bottom electrical connection structure 232. In some embodiments, the curvatures of the respective sides of bottom electrical connection structure 232 and micro LED 200 are the same, such that these two sides are parallel to each other and the gaps between the bottom electrical connection structures 232 and the adjacent micro LEDs 200 have uniform widths. In some alternative embodiments, the curvatures of these two sides may be different, such that these two sides are not parallel to each other and the gaps between the bottom electrical connection structures 232 and the adjacent micro LEDs 200 have nonuniform widths. Similarly, the other two of the four concave sides of the bottom electrical connection structure 232 face adjacent top electrical connection structures 231. The curvatures of these other two sides are generally similar to the curvatures of the adjacent top electrical connection structures 231. In some embodiments, the curvatures of these two sides are the same, such that these two sides are parallel to each other and the gaps between the bottom electrical connection structure 232 and adjacent top electrical connection structures 231 have uniform widths. In some alternative embodiments, the curvatures of these two sides may be different, such that these two sides are not parallel to each other and the gaps between the bottom electrical connection structures 232 and adjacent top electrical connection structures 231 have nonuniform widths.

As a result, the gaps 270 defined between adjacent ones of electrical connection structures 230 include first gaps 271 defined between adjacent ones of top electrical connection structures 231 and first bottom electrical connection structures 232a, second gaps 272 defined between adjacent ones of top electrical connection structures 231 and second bottom electrical connection structures 232b, and third gaps 273 defined between adjacent ones of first bottom electrical connection structures 232a and second bottom electrical connection structures 232b. Each of first and second gaps 271 and 272 is curved, i.e., flexural. Each of third gaps 273 is straight.

Light propagation channels may be defined between adjacent micro LEDs that are arranged diagonally. As illustrated in FIG. 9A, light propagation channel 370 is defined between micro LED 200a and micro LED 200d that are arranged along a hypothetical diagonal line h-h′. Light propagation channel 370 includes first gap 271, second gap 272, and third gaps 273a and 273b. Because first gap 271 and second gap 272 are curved, i.e., flexural, light propagation channel 370 is flexural. The light emitted from micro LED 200a and entering light propagation channel 370 is reflected multiple times by the sidewalls of gaps 271, 272, 273a, and 273b before the light reaches the adjacent micro LED 200d, and thus the intensity of the light that reaches the adjacent micro LED 200d is significantly reduced by the multiple reflections in gaps 271, 272, 273a, and 273b. As a result, the flexural light propagation channel 370 reduces the optical crosstalk between adjacent micro LEDs 200.

In micro LED array 900A, each one of third gaps 273 (including 273a and 273b) extends along a hypothetical diagonal line connecting the centers of adjacent ones of diagonally arranged micro LEDs 200. In addition, the diagonally arranged ones of third gaps 273 are aligned with each other. For example, as illustrated in FIG. 9A, both of third gap 273a and third gap 273b extend along diagonal line h-h′ connecting the centers of the adjacent ones of diagonally arranged micro LEDs 200a and 200d.

In some alternative embodiments, adjacent ones of diagonally arranged third gaps 273a and 273b may extend in the same direction, but may be parallel to each other. FIG. 9B schematically illustrates a partial top view of a micro LED array 900B according to such an embodiment. As illustrated in FIG. 9B, third gaps 273a and 273b extend in the same direction, and are not aligned with the diagonal line h-h′. Thus, instead of being aligned with each other, third gaps 273a and 273b are parallel to each other. In such an arrangement, the light that is emitted from micro LED 200a and enters light propagation channel 370 (including first gap 271, second gap 272, and third gaps 273a and 273b) is reduced compared to an arrangement in which third gaps 273a and 273b are aligned with the diagonal line h-h′. As a result, the optical crosstalk between the diagonally arranged micro LEDs 200a and 200d may be further reduced.

In still some alternative embodiments, the adjacent ones of diagonally arranged third gaps 273a and 273b may be aligned with each other, but may not be aligned with the hypothetical diagonal line connecting the centers of the adjacent ones of the diagonally arranged micro LEDs 200. FIG. 9C schematically illustrates a partial top view of a micro LED array 900C according to such an embodiment. As illustrated in FIG. 9C, third gap 273a is aligned with third gap 273b, but the extending directions of third gaps 273a and 273b are not connected to the centers of micro LEDs 200, i.e., not aligned with the diagonal line h-h′. In such an arrangement, the light that is emitted from micro LED 200a and enters light propagation channel 370 (including first gap 271, second gap 272, and third gaps 273a and 273b) is reduced compared to an arrangement in which third gaps 273a and 273b are aligned with the diagonal line h-h′. As a result, the optical crosstalk between adjacent micro LEDs 200 may be further reduced.

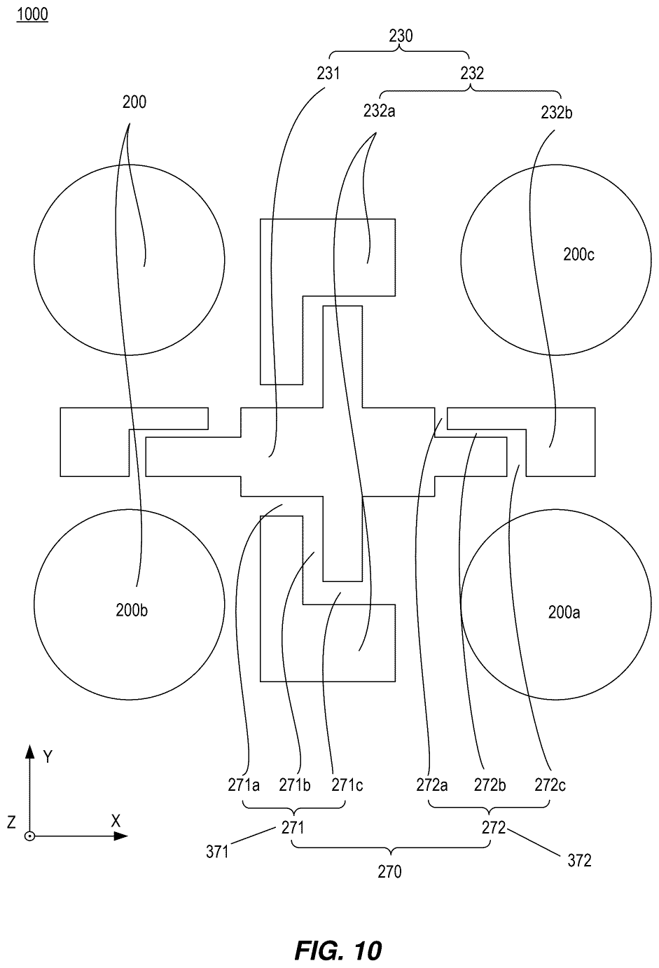

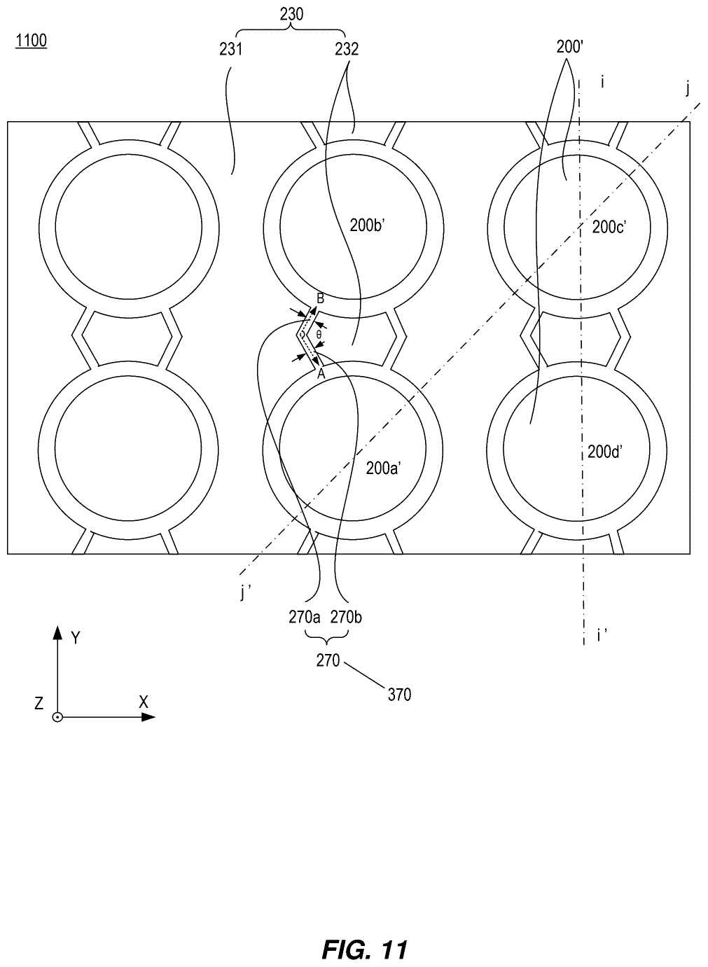

FIG. 10 schematically illustrates a top view of a micro LED array 1000 according to another embodiment of the present disclosure. As illustrated in FIG. 10, each top electrical connection structure 231 is formed to have a “plus” cross section, and each bottom electrical connection structure 232 is formed to have an “L” cross section. Each of gaps 270 is nonlinear and includes three sections, and each section extends along a direction crossing the direction along which adjacent section extends, thereby reducing the intensity of the light emitted from a micro LED 200 and transmitted to its adjacent micro LEDs 200. Specifically, as illustrated in FIG. 10, gaps 270 includes at least a first gap 271 between a top electrical connection structure 231 and a first bottom electrical connection structure 232a that are adjacent to each other and arranged along the Y-direction, and a second gap 272 between a top electrical connection structure 231 and a second bottom electrical connection structure 232b that are adjacent to each other and arranged along the X-direction. First gap 271 constitutes a light propagation channel 371 between micro LED 200a and micro LED 200b. Second gap 272 constitutes a light propagation channel 372 between micro LED 200a and micro LED 200c. First gap 271 includes a first section 271a extending along the X-direction, a second section 271b extending along the Y-direction, and a third section 271c extending along the X-direction. Because second section 271b extends along the Y-direction which crosses the X-direction along which adjacent sections 271a and 271c extend, light propagation channel 371 is nonlinear, i.e., flexural. Light emitted from micro LED 200a enters the flexural light propagation channel 371 and is reflected multiple times by the sidewalls of first to third sections 271a to 271c of first gap 271 while propagating through light propagation channel 371 before the light reaches adjacent micro LED 200b. Thus, the intensity of the light propagating through the flexural light propagation channel 371 is significantly reduced. Similarly, second gap 272 includes a first section 272a extending along the Y-direction, a second section 272b extending along the X-direction, and a third section 272c extending along the Y-direction. Because second section 272b extends along the X-direction which crosses the Y-direction along which adjacent sections 272a and 272c extend, light propagation channel 372 is nonlinear, i.e., flexural. Light emitted from micro LED 200a enters light propagation channel 372 and is reflected multiple times by the sidewalls of first to third sections 272a to 272c of second gap 272 while propagating through light propagation channel 372 before the light reaches adjacent micro LED 200c. Thus, the intensity of the light propagating through light propagation channel 372 is significantly reduced. As a result, the flexural light propagation channel 371 reduces the optical crosstalk between micro LEDs 200a and 200b arranged long the X-direction, and the flexural light propagation channel 372 reduces the optical crosstalk between micro LEDs 200a and 200c arranged long the Y-direction, thereby improving luminous efficiency of micro LED array 1000.

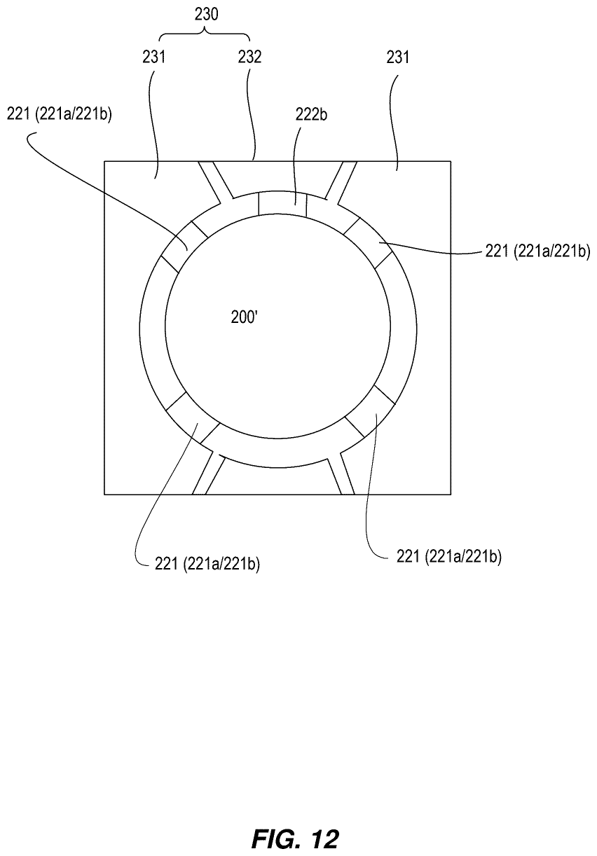

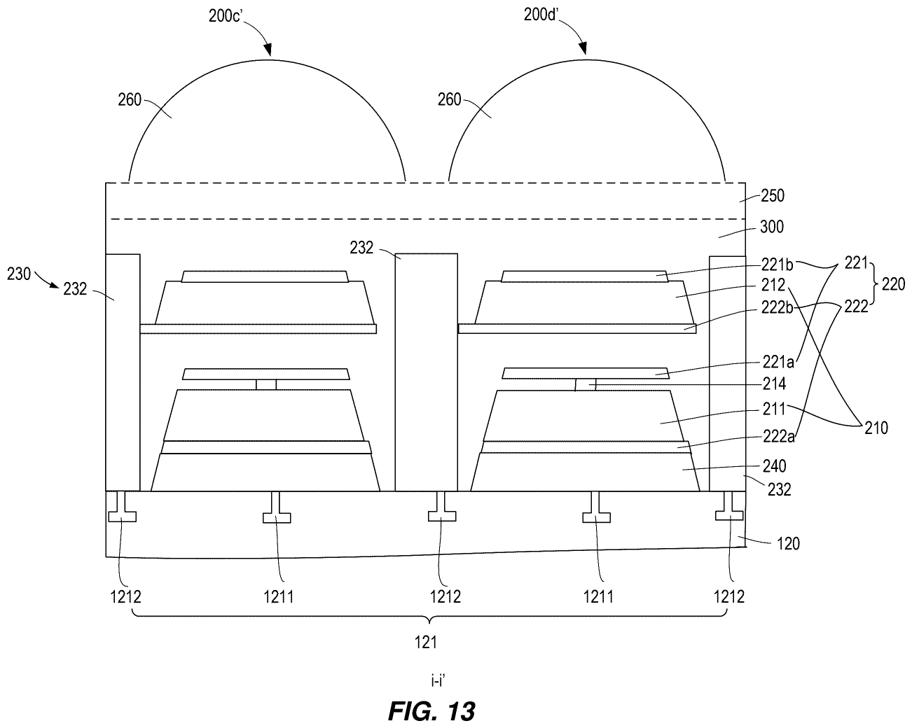

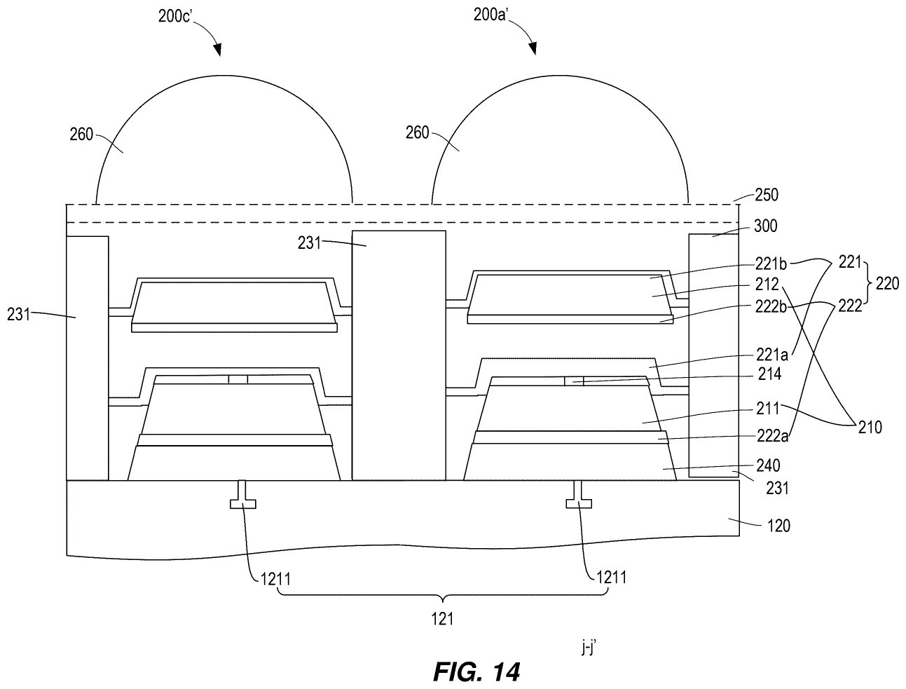

FIG. 11 schematically illustrates a top view of a micro LED array 1100 according to an embodiment of the present disclosure. FIG. 12 schematically illustrates a top view of a single micro LED 200′ and electrical connection structures 230 around the single micro LED 200′ in micro LED array 1100 of the embodiment shown in FIG. 11. FIG. 13 schematically illustrates a cross-sectional view of the structure of FIG. 11 along a section line i-i′. FIG. 14 schematically illustrates a cross-sectional view of the structure of FIG. 11 along a section line j-j′.

As illustrated in FIGS. 13 and 14, each micro LED 200′ includes two light emitting mesas 210, i.e., first light emitting mesa 211 and second light emitting mesa 212. As illustrated in FIGS. 12-14, electrical connection structures 230 includes a top electrical connection structure 231 (FIGS. 12 and 14) electrically connected to top conductive layer 221 (221a and 221b) of each light emitting mesa 210 (211 and 212), and a bottom electrical connection structure 232 (FIGS. 12 and 13) electrically connected to bottom conductive layer 222b of second light emitting mesa 212. For descriptions of other components in FIGS. 12-14, reference may be made to the descriptions the components of in FIGS. 2-5, and will not be repeated here.

Referring back to FIG. 11, each one of top electrical connection structures 231 is disposed between adjacent micro LEDs 200′ arranged along the X-direction, and extends along the Y-direction. Each one of bottom electrical connection structures 232 is disposed between adjacent micro LEDs 200′ arranged along the Y-direction. Gaps 270 are defined between adjacent electrical connection structures 230 arranged along the X-direction, i.e., between adjacent bottom electrical connection structures 232 and top electrical connection structures 231. Each gap 270 may be nonlinear, i.e., flexural. That is, each gap 270 may have at least two sections extending along directions that are not parallel to each other, or each gap 270 may be curved, or may include at least one curved section.

For example, in micro LED array 1100 illustrated in FIG. 11, gap 270 between adjacent bottom electrical connection structures 232 and top electrical connection structures 231 is nonlinear and includes a first section 270a extending along a first direction A and a second section 270b extending along a second direction B. First direction A and second direction B are not parallel to each other. In other words, first direction A crosses second direction B. An angle θ between first direction A and second direction B is more than 0° and less than 180°. Gap 270 constitutes a light propagation channel 370 between micro LED 200a′ and micro LED 200b′. Therefore, light emitted from micro LED 200a′ enters light propagation channel 370 and is reflected multiple times by the sidewalls of first and second sections 270a and 270b of gap 270 while propagating through light propagation channel 370 before the light reaches adjacent micro LED 200b′. Thus, the flexural light propagation channel 370 reduces the optical crosstalk between micro LEDs 200a′ and 200b′ arranged long the Y-direction.

According to the embodiments of the present disclosure, light propagation channels between adjacent micro LEDs include gaps defined between electrical connection structures are flexural. Therefore, the plurality of electrical connection structures may provide optical isolation and reduces crosstalk between adjacent micro LEDs, thereby improving light emitting efficiency.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED display panel, comprising:
a micro LED array comprising:
a plurality of micro LEDs; and
a plurality of electrical connection structures disposed around the plurality of micro LEDs and electrically connected to the plurality of micro LEDs,
wherein a plurality of light propagation channels are formed between adjacent ones of the micro LEDs, each light propagation channel including at least one of a plurality of gaps defined between adjacent ones of the electrical connection structures, and
from a top view of the micro LED array, the light propagation channels are flexural.

2. The micro LED display panel according to claim 1, wherein at least one of the plurality of gaps is nonlinear from the top view.

3. The micro LED display panel according to claim 1, wherein at least one of the plurality of gaps including at least a first section extending along a first direction and a second section extending along a second direction,
the first direction crossing the second direction.

4. The micro LED display panel according to claim 3, wherein an angle between the first direction and the second direction is between more than 0° and less than 180°.

5. The micro LED display panel according to claim 1, wherein each one of the plurality of micro LEDs comprises two or more light emitting mesas that are disposed in a vertical direction from top to bottom.

6. The micro LED display panel according to claim 5, wherein each one of the plurality of micro LEDs further comprises a dielectric material filled between the light emitting mesas, around the electrical connection structures, and around the micro LED.

7. The micro LED display panel according to claim 5, wherein the plurality of electrical connection structures comprise a plurality of top electrical connection structures configured to electrically connect to a top of each one of the two or more light emitting mesas, and a plurality of bottom electrical connection structures each configured to electrically connect to a bottom of one of the two or more light emitting mesas.

8. The micro LED display panel according to claim 1, wherein at least one of the plurality of gaps includes a curved section.

9. The micro LED display panel according to claim 1, wherein at least one of the plurality of gaps is curved.

10. The micro LED display panel according to claim 1, wherein each one of the plurality of micro LEDs comprises a first light emitting mesa, a second light emitting mesa, and a third light emitting mesa that are disposed in the vertical direction from top to bottom.

11. The micro LED display panel according to claim 10, wherein the first light emitting mesa emits blue light, the second light emitting mesa emits green light, and the third light emitting mesa emits red light.

12. The micro LED display panel according to claim 10, wherein the first light emitting mesa emits green light, the second light emitting mesa emits blue light, and the third light emitting mesa emits red light.

13. The micro LED display panel according to claim 1, further comprising a driving backplane formed at a back surface of the micro LED array and configured to control the plurality of micro LEDs.

14. The micro LED display panel according to claim 13, wherein each one of the plurality of micro LEDs comprises two or more light emitting mesas that are disposed in a vertical direction from top to bottom,
the micro LED further comprising a bottom connection mesa provided between a bottommost light emitting mesas and the driving backplane.

15. The micro LED display panel according to claim 14, where the plurality of electrical connection structures comprise a plurality of bottom electrical connection structures each configured to electrically connect to a bottom of one of the two or more light emitting mesas,
the driving backplane comprising:
a first solder joint electrically connected to the bottom connection mesa; and
a second solder joint electrically connected to at least one of the plurality of bottom electrical connection structures.

16. The micro LED display panel according to claim 1, further comprising a top insulating dielectric layer continuously formed on a top surface of the micro LED array.

17. The micro LED display panel according to claim 16, wherein the top insulating dielectric layer is transparent.

18. The micro LED display panel according to claim 16, further comprising a plurality of micro lenses provided on the top insulating dielectric layer, each of the micro lenses covering a pixel display area of one of the micro LEDs.

19. The micro LED display panel according to claim 1, wherein a width of each one of the gaps ranges from 50 nm to 2000 nm.

20. The micro LED display panel according to claim 1, wherein the plurality of electrical connection structures comprise a plurality of top electrical connection structures and a plurality of bottom electrical connection structures alternately arranged along a first direction,
a largest dimension of one of the bottom electrical connection structures is equal to or greater than a shortest distance between adjacent ones of top electrical connection structures along the first direction.

21. The micro LED display panel according to claim 1, wherein
the plurality of electrical connection structures comprise a plurality of top electrical connection structures, and a plurality of bottom electrical connection structures,
the plurality of bottom electrical connection structures include a plurality of first bottom electrical connection structures and a plurality of second bottom electrical connection structures,
the plurality of first bottom electrical connection structures and the plurality of micro LEDs are alternately arranged along a first direction,
the plurality of second bottom electrical connection structures and the plurality of micro LEDs are alternately arranged along a second direction,
the plurality of top electrical connection structures and the plurality of first bottom electrical connection structures are alternately arranged along the second direction, and
the plurality of top electrical connection structures and the plurality of second bottom electrical connection structures are alternately arranged along the first direction.

22. The micro LED display panel according to claim 21, wherein the plurality of gaps include:
a plurality of first gaps defined between adjacent ones of the top electrical connection structures and the first bottom electrical connection structures, and
a plurality of second gaps defined between adjacent ones of the top electrical connection structures and the second bottom electrical connection structures.

23. The micro LED display panel according to claim 22, wherein the plurality of gaps further include:
a plurality of third gaps defined between adjacent ones of the first bottom electrical connection structures and the second bottom electrical connection structures.

24. The micro LED display panel according to claim 23, wherein each one of the third gaps extends along a hypothetical diagonal line connecting the centers of adjacent ones of diagonally connected micro LEDs.

25. The micro LED display panel according to claim 23, wherein adjacent ones of diagonally arranged third gaps are parallel to each other.

26. The micro LED display panel according to claim 23, wherein adjacent ones of diagonally arranged third gaps are aligned with each other.

27. The micro LED display panel according to claim 23, wherein extending directions of the adjacent ones of diagonally arranged third gaps are not along a hypothetical diagonal line connecting the centers of adjacent ones of diagonally connected micro LEDs.

28. A micro LED display panel, comprising:
a micro LED array comprising:
a plurality of micro LEDs; and
a plurality of electrical connection structures disposed around the plurality of micro LEDs and electrically connected to the plurality of micro LEDs,
wherein the plurality of electrical connection structures include a first electrical connection structure and a second electrical connection structure adjacent to each other,
the first electrical connection structure comprises a first side facing the second electrical connection structure,
the second electrical connection structure comprises a second side facing the first electrical connection structure, and
both of the first side and the second side are nonlinear.

29. The micro LED display panel according to claim 28, wherein the first side of the first electrical connection structure and the second side of the second electrical connection structure are in conformance with each other.

30. The micro LED display panel according to claim 28, wherein a gap is defined between the first side of the first electrical connection structure and the second side of the second electrical connection structure.

31. The micro LED display panel according to claim 30, wherein a width of the gap ranges from 50 nm to 2000 nm.

32. The micro LED display panel according to claim 28, wherein the first side of the first electrical connection structure defines a protrusion that protrudes towards the second electrical connection structure, and the second side of the second electrical connection structure defines a recess that is recessed for accommodating the protrusion.

33. The micro LED display panel according to claim 28, wherein the first side of the first electrical connection structure has a convex shape, and the second side of the second electrical connection structure has a concave shape.

34. The micro LED display panel according to claim 28, wherein the first electrical connection structure and the second electrical connection structure are arranged along a first direction, and
each one of the first side of the first electrical connection structure and the second side of the second electrical connection structure includes at least one section that is not parallel to a second direction that is perpendicular to the first direction.

35. The micro LED display panel according to claim 28, wherein each one of the first side of the first electrical connection structure and the second side of the second electrical connection structure includes at least two sections extending along different directions.

36. The micro LED display panel according to claim 28, wherein each one of the first side of the first electrical connection structure and the second side of the second electrical connection structure includes a curved section.

37. The micro LED display panel according to claim 28, wherein the plurality of electrical connection structures comprise a plurality of first electrical connection structures and a plurality of second electrical connection structures alternately arranged along a first direction.

38. The micro LED display panel according to claim 37, wherein a largest dimension of one of the first electrical connection structures along the first direction is equal to or greater than a shortest distance between adjacent ones of second electrical connection structures along the first direction.

39. A method for reducing optical crosstalk between light emitting units in a display panel,
the display panel comprising:
a plurality of light emitting units; and
a plurality of electrical connection structures disposed around the plurality of light emitting units and electrically connected to the plurality of light emitting units, the electrical connection structures being spaced apart from each other to define a plurality of gaps therebetween,
the method comprising:
reflecting light emitted by one of the light emitting units by at least a portion of one of the electrical connection structures disposed on a light propagation path of the light emitting unit.

40. The method according to claim 39, wherein the reflecting the light comprises:
after a portion of the light emitted by the light emitting unit enters the gap between adjacent ones of the electrical connection structures, reflecting the light by at least a portion of at least one of the adjacent electrical connection structures.

41. The method according to claim 39, wherein the reflecting the light comprising:
reflecting a portion of the light back towards the light emitting unit by the one of the electrical connection structures disposed on the light propagation path of the light emitting unit.
